(19) United States
(12) Patent Application Publication
(10) Pub. No.: US 2020/0292739 A1
(43) Pub. Date: Sep. 17, 2020

(54) IMAGE DISPLAY APPARATUS AND CIRCULARLY POLARIZING PLATE TO BE USED IN THE IMAGE DISPLAY APPARATUS

(71) Applicant: NITTO DENKO CORPORATION, Osaka (JP)

(72) Inventors: Hiroshi Tomohisa, Ibaraki-shi (JP); Katsunori Takada, Ibaraki-shi (JP)

(73) Assignee: NITTO DENKO CORPORATION, Osaka (JP)

(21) Appl. No.: 16/815,156

(22) Filed: Mar. 11, 2020

(30) Foreign Application Priority Data
Mar. 13, 2019 (JP) 2019-045702

(51) Int. Cl. G02B 5/30; H01L 27/32; H01L 51/00; H01L 51/52

(52) U.S. Cl. CPC G02B 5/3016; H01L 27/3244; H01L 2251/5338; H01L 51/5281; H01L 51/0097

(57) ABSTRACT

An image display apparatus includes: a first image display portion; a second image display portion; and a bending center. The first image display portion and the second image display portion are formed so as to be bendable at the bending center. The first image display portion has a first polarizer, a first retardation layer, and a first display cell in the stated order from a viewer side. The second image display portion has a second polarizer, a second retardation layer, and a second display cell in the stated order from the viewer side. The first polarizer and the second polarizer are arranged so that respective absorption axes thereof are in a line-symmetric relationship with respect to the bending center. The first retardation layer and the second retardation layer are arranged so that respective slow axes thereof are in a line-symmetric relationship with respect to the bending center.

### BACKGROUND OF THE INVENTION

This application claims priority under 35 U.S.C. Section 119 to Japanese Patent Application No. 2019-045702 filed on Mar. 13, 2019 which is herein incorporated by reference.

### 1. FIELD OF THE INVENTION

The present invention relates to an image display apparatus and a circularly polarizing plate to be used in the image display apparatus.

### 2. DESCRIPTION OF THE RELATED ART

Image display apparatus typified by a liquid crystal display apparatus and an electroluminescence (EL) display apparatus (e.g., an organic EL display apparatus or an inorganic EL display apparatus) have been rapidly spreading. Further, in recent years, the development of a bendable or foldable image display apparatus has been advanced (for example, Japanese Patent Application Laid-open No. 2017-203987). However, the bendable or foldable image display apparatus involves the following problem. When an image is viewed under a state in which the apparatus is bent, a difference in tint occurs between the images on both sides of a bending portion.

### SUMMARY OF THE INVENTION

The present invention has been made to solve the conventional problem, and a primary object of the present invention is to provide an image display apparatus having the following feature: when an image is viewed under a state in which the apparatus is bent, a difference in regular reflection hue between the images on both sides of a bending portion is small.

An image display apparatus according to at least one embodiment of the present invention includes: a first image display portion; a second image display portion; and a bending center defined as a straight line of a connecting portion between one side of the first image display portion and one side of the second image display portion. The first image display portion and the second image display portion are formed so as to be bendable at the bending center. The first image display portion has a first polarizer, a first retardation layer having a circular polarization function or an elliptical polarization function, and a first display cell in the stated order from a viewer side. The second image display portion has a second polarizer, a second retardation layer having a circular polarization function or an elliptical polarization function, and a second display cell in the stated order from the viewer side. The first polarizer and the second polarizer are arranged so that respective absorption axes thereof are in a line-symmetric relationship with respect to the bending center. The first retardation layer and the second retardation layer are arranged so that respective slow axes thereof are in a line-symmetric relationship with respect to the bending center.

In at least one embodiment, a regular reflection hue (a*₁, b*₁) of the first image display portion in a direction at a polar angle of 30° and a regular reflection hue (a*₂, b*₂) of the second image display portion in the direction at a polar angle of 30° satisfy the following relationships.

|a*₁−a*₂|<1.00

|b*₁−b*₂|<1.00

In at least one embodiment, each of the first retardation layer and the second retardation layer is a single layer, and each of the retardation layers has an Re(550) of from 100 nm to 180 nm, and an angle formed by the slow axis of the first retardation layer and the absorption axis of the first polarizer is from 40° to 50°, and an angle formed by the slow axis of the second retardation layer and the absorption axis of the second polarizer is from 40° to 50°.

In at least one embodiment, the first image display portion further has a retardation layer showing a refractive index characteristic of nz>nx=ny between the first retardation layer and the first display cell, and the second image display portion further has a retardation layer showing a refractive index characteristic of nz>nx=ny between the second retardation layer and the second display cell.

In at least one embodiment, each of the first retardation layer and the second retardation layer has a laminated structure of an H layer and a Q layer, each of the H layers has an Re(550) of from 200 nm to 300 nm, and each of the Q layers has an Re(550) of from 100 nm to 180 nm, and an angle formed by a slow axis of the H layer of the first retardation layer and the absorption axis of the first polarizer is from 10° to 20°, and an angle formed by a slow axis of the Q layer of the first retardation layer and the absorption axis of the first polarizer is from 70° to 80°, and an angle formed by a slow axis of the H layer of the second retardation layer and the absorption axis of the second polarizer is from 10° to 20°, and an angle formed by a slow axis of the Q layer of the second retardation layer and the absorption axis of the second polarizer is from 70° to 80°.

In at least one embodiment, the first image display portion and the second image display portion are integrated with each other, and the bending center is defined as a boundary between the first image display portion and the second image display portion.

In at least one embodiment, the image display apparatus is an organic electroluminescence display apparatus.

According to another aspect of the present invention, there is provided a circularly polarizing plate to be used in the image display apparatus as described above. A circularly polarizing plate according to at least one embodiment of the present invention includes: a first portion corresponding to the first image display portion; a second portion corresponding to the second image display portion; and a bending center. The first portion and the second portion are integrated with each other. The bending center is defined as a boundary between the first portion and the second portion. The first portion has a first polarizer, and a first retardation layer having a circular polarization function or an elliptical polarization function. The second portion has a second polarizer, and a second retardation layer having a circular polarization function or an elliptical polarization function. The first polarizer and the second polarizer are arranged so that respective absorption axes thereof are in a line-symmetric relationship with respect to the bending center, and the first retardation layer and the second retardation layer are arranged so that respective slow axes thereof are in a line-symmetric relationship with respect to the bending center.

In at least one embodiment, each of the first retardation layer and the second retardation layer is an alignment fixed layer of a liquid crystal compound.

In at least one embodiment, each of the first polarizer and the second polarizer is an alignment fixed layer of a liquid crystal compound.

According to at least one embodiment of the present invention, in the bendable or foldable image display apparatus, the absorption axes of the polarizers of the image display portions on both sides of the bending portion are brought into a line-symmetric positional relationship with respect to the bending portion, and the slow axes of the retardation layers thereof are also brought into a line-symmetric positional relationship with respect thereto. Accordingly, the image display apparatus having the following feature can be obtained: when an image is viewed under a state in which the apparatus is bent, a difference in regular reflection hue between the images on both sides of the bending portion is small.

### BRIEF DESCRIPTION OF THE DRAWINGS

FIG. 1 is a schematic plan view when an image display apparatus according to at least one embodiment of the present invention is viewed from a viewer side.

FIG. 2A is a schematic sectional view of the image display apparatus of FIG. 1 taken along the line II-II, and FIG. 2B is a schematic sectional view for illustrating a state in which the image display apparatus of FIG. 2A is bent.

FIG. 3 is a schematic sectional view for illustrating a state in which an image display apparatus according to at least one embodiment of the present invention is bent.

FIG. 4A, FIG. 4B, and FIG. 4C are each a schematic plan view for illustrating a modification example of a relationship between the absorption axis directions of polarizers and the slow axis directions of retardation layers in the image display apparatus of each of FIG. 1, FIG. 2A, and FIG. 2B.

FIG. 5 is a schematic sectional view of an image display apparatus according to at least one embodiment of the present invention.

FIG. 6 is a photographic image showing comparison between the states of the reflection hues of the left screen and right screen of an organic EL display apparatus of Example 1, and the states of the reflection hues of the left screen and right screen of an organic EL display apparatus of Comparative Example 1.

### DESCRIPTION OF THE EMBODIMENTS

Embodiments of the present invention are described below. However, the present invention is not limited to these embodiments.

### Definitions of Terms and Symbols

The definitions of terms and symbols used herein are as described below.

### (1) Refractive Indices (nx, ny, and nz)

“nx” represents a refractive index in a direction in which an in-plane refractive index is maximum (that is, slow axis direction), “ny” represents a refractive index in a direction perpendicular to the slow axis in the plane (that is, fast axis direction), and “nz” represents a refractive index in a thickness direction.

### (2) In-Plane Retardation (Re)

“Re(λ)” refers to an in-plane retardation measured at 23° C. with light having a wavelength of λ nm. For example, “Re(550)” refers to an in-plane retardation measured at 23° C. with light having a wavelength of 550 nm. The Re(λ) is determined from the equation “Re(λ)=(nx-ny)×d” when the thickness of a layer (film) is represented by d (nm).

### (3) Thickness Direction Retardation (Rth)

“Rth(λ)” refers to a thickness direction retardation measured at 23° C. with light having a wavelength of λ nm. For example, “Rth(550)” refers to a thickness direction retardation measured at 23° C. with light having a wavelength of 550 nm. The Rth(A) is determined from the equation “Rth(λ)=(nx-nz)×d” when the thickness of a layer (film) is represented by d (nm).

### (4) Nz Coefficient

An Nz coefficient is determined from the equation “Nz=Rth/Re”.

### (5) Angle

When reference is made to an angle in the present specification, the angle encompasses angles in both of a clockwise direction and a counterclockwise direction unless otherwise stated.

### A. Overall Configuration of Image Display Apparatus

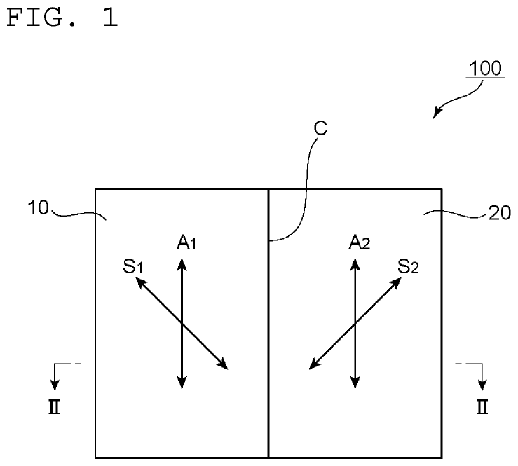

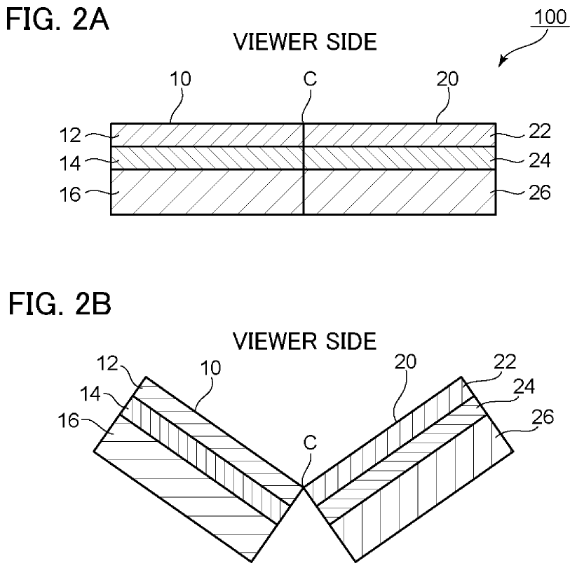

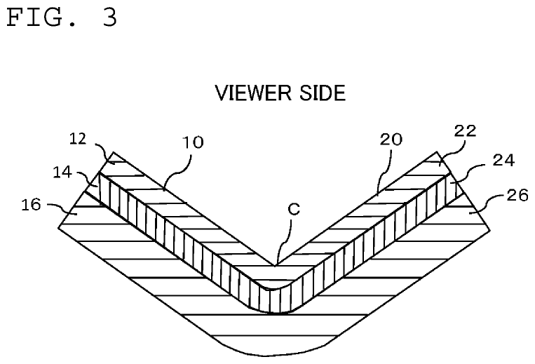

FIG. 1 is a schematic plan view when an image display apparatus according to at least one embodiment of the present invention is viewed from a viewer side. FIG. 2A is a schematic sectional view of the image display apparatus of FIG. 1 taken along the line II-II, and FIG. 2B is a schematic sectional view for illustrating a state in which the image display apparatus of FIG. 2A is bent. FIG. 3 is a schematic sectional view for illustrating a state in which an image display apparatus according to at least one embodiment of the present invention is bent. An image display apparatus 100 includes: a first image display portion 10; a second image display portion 20; and a bending center C defined as the straight line of a connecting portion between one side of the first image display portion 10 and one side of the second image display portion 20. In the image display apparatus 100, the first image display portion 10 and the second image display portion 20 are formed so as to be bendable at the bending center C, and are formed so as to be foldable at the center in at least one embodiment. The first image display portion 10 has a first polarizer 12, a first retardation layer 14 having a circular polarization function or an elliptical polarization function, and a first display cell 16 in the stated order from the viewer side. The second image display portion 20 has a second polarizer 22, a second retardation layer 24 having a circular polarization function or an elliptical polarization function, and a second display cell 26 in the stated order from the viewer side. In at least one embodiment of the present invention, the first polarizer 12 and the second polarizer 22 are arranged so that the absorption axis A₁ of the first polarizer 12 and the absorption axis A₂ of the second polarizer 22 are in a line-symmetric relationship with respect to the bending center C (i.e., so that the absorption axes overlap each other when the apparatus is folded at the bending center C). Further, the first retardation layer 14 and the second retardation layer 24 are arranged so that the slow axis S₁ of the first retardation layer 14 and the slow axis S₂ of the second retardation layer 24 are in a line-symmetric relationship with respect to the bending center C. With such configuration, an image display apparatus having the following feature can be obtained: when an image is viewed under a state in which the apparatus is bent, a difference in regular reflection hue between the images on both sides of a bending portion is small. In the image display apparatus, the first image display portion 10 and the second image display portion 20 connected to each other as illustrated in FIG. 2B may be formed so as to be bendable, or the first image display portion 10 and the second image display portion 20 integrated with each other as illustrated in FIG. 3 may be formed so as to be bendable. In the embodiment of FIG. 3, the bending center C is defined as a boundary between the first image display portion 10 and the second image display portion 20.

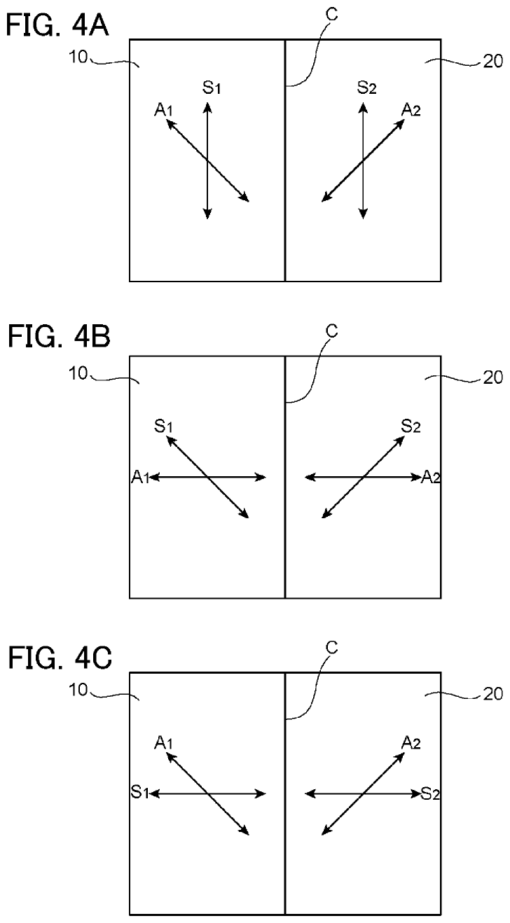

In at least one embodiment of the present invention, as described above, the following conditions only need to be satisfied: the absorption axis A₁ of the first polarizer 12 and the absorption axis A₂ of the second polarizer 22 are in a line-symmetric relationship with respect to the bending center C; and the slow axis S₁ of the first retardation layer 14 and the slow axis S₂ of the second retardation layer 24 are in a line-symmetric relationship with respect thereto. Therefore, a relationship between the axial directions of the absorption axes A₁ and A₂, and the slow axes S₁ and S₂ is not limited to the configuration illustrated in FIG. 1, and any appropriate line-symmetric relationship may be adopted. Typical examples of the line-symmetric relationship include configurations illustrated in FIG. 4A to FIG. 4C. The line-symmetric relationship is preferably the configuration illustrated in FIG. 1. With such configuration, the production efficiency of the image display apparatus is excellent, and the adjustment of the axial relationship is easy. Further, with such configuration, it may be possible to bond a single film to the first image display portion and the second image display portion at one time.

In at least one embodiment, in the image display apparatus 100, a regular reflection hue (a*₁, b*₁) of the first image display portion 10 in a direction at a polar angle of 30° and a regular reflection hue (a*₂, b*₂) of the second image display portion 20 in the direction at a polar angle of 30° satisfy the below-indicated relationships. In this case, for example, an azimuth angle in a left screen may be from 110° to 130°, and an azimuth angle in a right screen may be from 50° to 70°.

|a*₁−a*₂|<1.00

|b*₁−b*₂|<1.00

That is, according to at least one embodiment of the present invention, the adoption of such configuration as described above can provide an image display apparatus having the following feature: when an image is viewed under a state in which the apparatus is bent, a difference in regular reflection hue between the images on both sides of a bending portion is small. The |a*₁−a*₂| is preferably 0.50 or less, more preferably 0.30 or less, still more preferably 0.20 or less, particularly preferably 0.10 or less. The |b*₁−b*₂| is also preferably 0.50 or less, more preferably 0.30 or less, still more preferably 0.20 or less, particularly preferably 0.10 or less. Each of the |a*₁−a*₂| and the |b*₁−b*₂| is preferably as small as possible, and is most preferably zero.

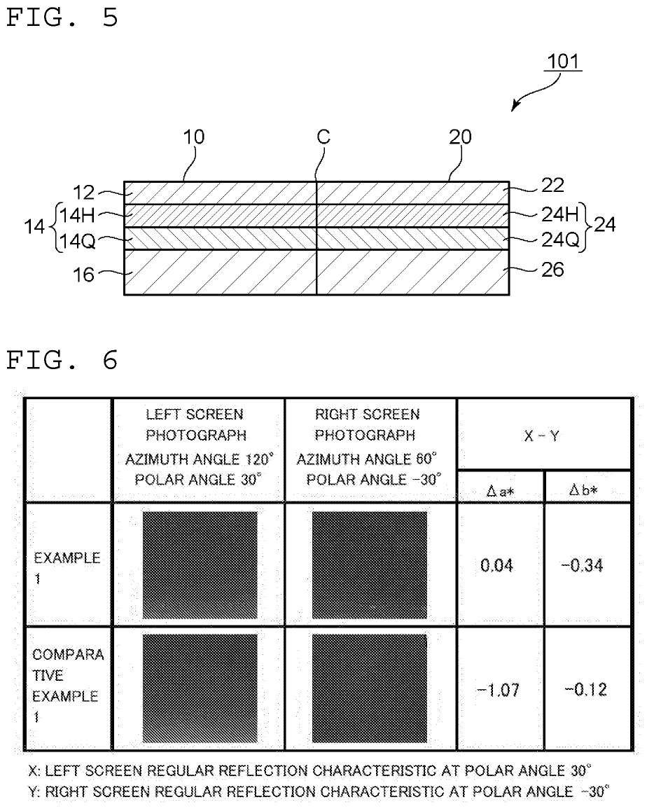

Each of the first retardation layer 14 and the second retardation layer 24 may be such a single layer as illustrated in FIG. 2A, or may have such a laminated structure of an H layer 14H, 24H and a Q layer 14Q, 24Q as illustrated in FIG. 5. Each of the configurations is described below. The axial relationships of FIG. 1 and FIG. 4A to FIG. 4C are each an illustration of a configuration in the case where the first retardation layer 14 and the second retardation layer 24 are each a single layer.

In the case where the first retardation layer 14 and the second retardation layer 24 are each a single layer, the first retardation layer 14 and the second retardation layer 24 may each typically function as a λ/4 plate. Specifically, the Re(550) of each of the retardation layers is preferably from 100 nm to 180 nm. In this case, an angle formed by the slow axis of the first retardation layer 14 and the absorption axis of the first polarizer 12 is preferably from 40° to 50°, and an angle formed by the slow axis of the second retardation layer 24 and the absorption axis of the second polarizer 22 is preferably from 40° to 50°. In this embodiment, the first image display portion 10 may further have a retardation layer showing a refractive index characteristic of nz>nx=ny (not shown) between the first retardation layer 14 and the first display cell 16. Similarly, the second image display portion 20 may further have a retardation layer showing a refractive index characteristic of nz>nx=ny (not shown) between the second retardation layer 24 and the second display cell 26. In this specification, the retardation layer showing a refractive index characteristic of nz>nx=ny is sometimes referred to as “another retardation layer”.

In the case where the first retardation layer 14 and the second retardation layer 24 each have a laminated structure, the first retardation layer 14 typically has the H layer 14H and the Q layer 14Q, and the second retardation layer 24 typically has the H layer 24H and the Q layer 24Q. The H layers 14H and 24H may each typically function as a λ/2 plate, and the Q layers 14Q and 24Q may each typically function as a λ/4 plate. Specifically, the Re(550) of each of the H layers is preferably from 200 nm to 300 nm, and the Re(550) of each of the Q layers is preferably from 100 nm to 180 nm. In this case, an angle formed by the slow axis of the H layer 14H of the first retardation layer and the absorption axis of the first polarizer 12 is preferably from 10° to 20°, and an angle formed by the slow axis of the Q layer 14Q of the first retardation layer and the absorption axis of the first polarizer 12 is preferably from 70° to 80°. Similarly, an angle formed by the slow axis of the H layer 24H of the second retardation layer and the absorption axis of the second polarizer 22 is preferably from 10° to 20°, and an angle formed by the slow axis of the Q layer 24Q of the second retardation layer and the absorption axis of the second polarizer 22 is preferably from 70° to 80°. The order in which the H layer and the Q layer in each laminated structure are arranged may be opposite to that illustrated in FIG. 5, and the angle formed by the slow axis of the H layer and the absorption axis of the polarizer, and the angle formed by the slow axis of the Q layer and the absorption axis of the polarizer in each laminated structure may be opposite to those described above.

The first polarizer 12 and the second polarizer 22 may be identical to each other, or may be different from each other in detailed configuration. Similarly, the first retardation layer 14 and the second retardation layer 24 may be identical to each other, or may be different from each other in detailed configuration. In addition, a protective layer (not shown) may be arranged on one side, or each of both sides, of each of the first polarizer 12 and the second polarizer 22.

The present invention may be applied to any appropriate bendable image display apparatus. Typical examples of the image display apparatus include an organic electroluminescence (EL) display apparatus, a liquid crystal display apparatus, and a quantum dot display apparatus. Of those, the organic EL display apparatus is preferred. The effect of the present invention is significant in the organic EL display apparatus. With regard to the configuration of the image display apparatus, a configuration well known in the art may be adopted for a matter that is not described herein.

The polarizers, the protective layer (if present), and the retardation layers that are constituents for the image display apparatus are specifically described below. The respective layers and an optical film forming the image display apparatus are laminated via any appropriate adhesion layer (e.g., a pressure-sensitive adhesive layer or an adhesive layer) unless otherwise stated. In the following description, the first polarizer 12 and the second polarizer 22 are collectively described as “polarizer”, and the first retardation layer 14 and the second retardation layer 24 are collectively described as “retardation layer”.

### B. Polarizer

Any appropriate polarizer may be adopted as the polarizer. For example, a resin film forming the polarizer may be a single-layer resin film, or may be a laminate of two or more layers.

Specific examples of the polarizer including a single-layer resin film include: a polarizer obtained by subjecting a hydrophilic polymer film, such as a polyvinyl alcohol (PVA)-based film, a partially formalized PVA-based film, or an ethylene-vinyl acetate copolymer-based partially saponified film, to dyeing treatment with a dichroic substance, such as iodine or a dichroic dye, and stretching treatment; and a polyene-based alignment film, such as a dehydration-treated product of PVA or a dehydrochlorination-treated product of polyvinyl chloride. A polarizer obtained by dyeing the PVA-based film with iodine and uniaxially stretching the resultant is preferably used because the polarizer is excellent in optical characteristics.

The dyeing with iodine is performed by, for example, immersing the PVA-based film in an aqueous solution of iodine. The stretching ratio of the uniaxial stretching is preferably from 3 times to 7 times. The stretching may be performed after the dyeing treatment, or may be performed while the dyeing is performed. In addition, the dyeing may be performed after the stretching has been performed. The PVA-based film is subjected to swelling treatment, cross-linking treatment, washing treatment, drying treatment, or the like as required. For example, when the PVA-based film is immersed in water to be washed with water before the dyeing, contamination or an antiblocking agent on the surface of the PVA-based film can be washed off. In addition, the PVA-based film is swollen and hence dyeing unevenness or the like can be prevented.

The polarizer obtained by using the laminate is specifically, for example, a polarizer obtained by using a laminate of a resin substrate and a PVA-based resin layer (PVA-based resin film) laminated on the resin substrate, or a laminate of a resin substrate and a PVA-based resin layer formed on the resin substrate through application. The polarizer obtained by using the laminate of the resin substrate and the PVA-based resin layer formed on the resin substrate through application may be produced by, for example, a method involving: applying a PVA-based resin solution onto the resin substrate; drying the solution to form the PVA-based resin layer on the resin substrate, to thereby provide the laminate of the resin substrate and the PVA-based resin layer; and stretching and dyeing the laminate to turn the PVA-based resin layer into the polarizer. In this embodiment, the stretching typically includes the stretching of the laminate under a state in which the laminate is immersed in an aqueous solution of boric acid. The stretching may further include the aerial stretching of the laminate at high temperature (e.g., 95° C. or more) before the stretching in the aqueous solution of boric acid as required. The resultant laminate of the resin substrate and the polarizer may be used as it is (i.e., the resin substrate may be used as a protective layer for the polarizer). Alternatively, a product obtained as described below may be used: the resin substrate is peeled from the laminate of the resin substrate and the polarizer, and any appropriate protective layer in accordance with purposes is laminated on the peeling surface. Details about such method of producing a polarizer are described in, for example, Japanese Patent Application Laid-open No. 2012-73580. The entire description of the publication is incorporated herein by reference.

Another example of the polarizer obtained by using the laminate is a polarizer formed as an alignment fixed layer of a liquid crystal compound (hereinafter sometimes referred to as “liquid crystalline polarizer”). The liquid crystalline polarizer is, for example, a liquid crystalline polarizer obtained by applying a liquid crystalline coating liquid to a resin substrate and drying the liquid. The liquid crystalline polarizer contains, for example, an aromatic disazo compound represented by the following formula (1):

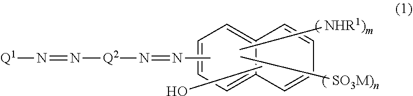

in the formula (1), Q¹ represents a substituted or unsubstituted aryl group, Q² represents a substituted or unsubstituted arylene group, R¹s each independently represent a hydrogen atom, a substituted or unsubstituted alkyl group, a substituted or unsubstituted acetyl group, a substituted or unsubstituted benzoyl group, or a substituted or unsubstituted phenyl group, M represents a counter ion, “m” represents an integer of from 0 to 2, and “n” represents an integer of from 0 to 6; provided that at least one of “m” or “n” does not represent 0, and a relationship of 1≤m+n≤6 is satisfied, and when “m” represents 2, the respective R¹s may be identical to or different from each other.

The liquid crystalline polarizer may be produced by, for example, a method including the following step B and step C. As required, a step A may be performed before the step B, and a step D may be performed after the step C.

Step A: A step of subjecting the surface of the substrate to alignment treatment.

Step B: A step of applying a coating liquid containing the aromatic disazo compound represented by the formula (1) to the surface of the substrate to form a coating film.

Step C: A step of drying the coating film to forma polarizer that is a dried coating film.

Step D: A step of subjecting the surface of the polarizer obtained in the step C to water-resisting treatment.

Another example of the liquid crystalline polarizer is a polarizer obtained by applying a composition containing a polymerizable liquid crystal compound, a polymerizable non-liquid crystal compound, a dichroic dye, a polymerization initiator, and a solvent to the substrate, and copolymerizing the composition. The term “alignment fixed layer of a liquid crystal compound” as used herein also comprehends a layer (cured layer) obtained by the (co)polymerization of such polymerizable liquid crystal compound.

Details about constituent materials for the liquid crystalline polarizer and a manufacturing method therefor are described in, for example, Japanese Patent Application Laid-open No. 2009-173849, Japanese Patent Application Laid-open No. 2018-151603, and Japanese Patent Application Laid-open No. 2018-84845. The descriptions of those publications are incorporated herein by reference.

The thickness of the polarizer (iodine-based polarizer) is preferably 25 μm or less, more preferably from 1 μm to 12 μm, still more preferably from 3 μm to 12 μm, particularly preferably from 3 μm to 8 μm. When the thickness of the polarizer falls within such range, its curling at the time of heating can be satisfactorily suppressed, and satisfactory appearance durability at the time of the heating is obtained. The thickness of the liquid crystalline polarizer is preferably 1,000 nm or less, more preferably 700 nm or less, particularly preferably 500 nm or less. The lower limit of the thickness of the liquid crystalline polarizer is preferably 100 nm, more preferably 200 nm, particularly preferably 300 nm.

The polarizer preferably shows absorption dichroism at any wavelength in the wavelength range of from 380 nm to 780 nm. The single layer transmittance of the polarizer is from 42.0% to 46.0%, preferably from 44.5% to 46.0%. The polarization degree of the polarizer is preferably 97.0% or more, more preferably 99.0% or more, still more preferably 99.9% or more.

### C. Protective Layer

The protective layer is formed of any appropriate film that may be used as a protective layer for a polarizer. A material serving as a main component of the film is specifically, for example: a cellulose-based resin, such as triacetylcellulose (TAC); a transparent resin, such as a polyester-based, polyvinyl alcohol-based, polycarbonate-based, polyamide-based, polyimide-based, polyether sulfone-based, polysulfone-based, polystyrene-based, polynorbornene-based, polyolefin-based, (meth) acrylic, or acetate-based transparent resin; or a thermosetting resin or a UV-curable resin, such as a (meth) acrylic, urethane-based, (meth) acrylic urethane-based, epoxy-based, or silicone-based thermosetting resin or UV-curable resin. A further example thereof is a glassy polymer, such as a siloxane-based polymer. In addition, a polymer film described in Japanese Patent Application Laid-open No. 2001-343529 (WO 01/37007 A1) may be used. For example, a resin composition containing a thermoplastic resin having a substituted or unsubstituted imide group on a side chain thereof, and a thermoplastic resin having a substituted or unsubstituted phenyl group and a nitrile group on side chains thereof may be used as the material for the film, and the composition is, for example, a resin composition containing an alternating copolymer formed of isobutene and N-methylmaleimide, and an acrylonitrile-styrene copolymer. The polymer film may be, for example, an extrudate of the resin composition.

In the case where the protective layer is arranged on the viewer side (the side opposite to the retardation layer) of the polarizer, the protective layer may be subjected to surface treatment, such as hard coat treatment, antireflection treatment, anti-sticking treatment, or antiglare treatment, as required.

In the case where the protective layer is arranged between the polarizer and the retardation layer, it is preferred that the protective layer be optically isotropic. The phrase “be optically isotropic” as used herein refers to having an in-plane retardation Re(550) of from 0 nm to 10 nm and a thickness direction retardation Rth(550) of from −10 nm to +10 nm.

Any appropriate thickness may be adopted as the thickness of the protective layer. The thickness of the protective layer is, for example, from 15 μm to 45 μm, preferably from 20 μm to 40 μm. When the protective layer is subjected to surface treatment, its thickness is a thickness including the thickness of a surface-treated layer.

### D. Retardation Layers

### D-1. Single-Layer Retardation Layer

When the retardation layers are each a single layer, as described above, the retardation layers may each typically function as a λ/4 plate. The retardation layers are typically arranged for imparting an antireflection characteristic to the image display apparatus. The refractive index characteristic of each of the retardation layers typically shows a relationship of nx>ny=nz. The in-plane retardation Re(550) of each of the retardation layers is preferably from 100 nm to 180 nm, more preferably from 110 nm to 170 nm, still more preferably from 120 nm to 160 nm. Herein, “ny=nz” encompasses not only a case in which ny and nz are exactly equal to each other, but also a case in which ny and nz are substantially equal to each other. Therefore, a relationship of ny>nz or ny<nz may be satisfied without impairing the effects of the present invention.

The Nz coefficient of each of the retardation layers is preferably from 0.9 to 1.5, more preferably from 0.9 to 1.3. When such relationship is satisfied, an image display apparatus having an extremely excellent reflection hue can be obtained.

The retardation layers may each show a reverse wavelength dispersion characteristic, i.e., a retardation value increasing with an increase in wavelength of measurement light, may show a positive wavelength dispersion characteristic, i.e., a retardation value decreasing with an increase in wavelength of measurement light, or may show a flat wavelength dispersion characteristic, i.e., a retardation value hardly changing even when the wavelength of measurement light changes. In at least one embodiment, the retardation layers each show a reverse wavelength dispersion characteristic. In this case, the Re(450)/Re(550) of each of the retardation layers is preferably 0.8 or more and less than 1, more preferably 0.8 or more and 0.95 or less. With such configuration, an extremely excellent antireflection characteristic can be achieved.

As described above, the angle formed by the slow axis of each of the retardation layers and the absorption axis of the corresponding polarizer is preferably from 40° to 50°, more preferably from 42° to 48°, still more preferably about 45°. When the angle falls within such range, an image display apparatus having an extremely excellent antireflection characteristic can be obtained by using the retardation layers as λ/4 plates as described above.

The retardation layers may each include any appropriate material as long as such characteristics as described above may be satisfied. Specifically, the retardation layers may each be a stretched film of a resin film, or may each be an alignment fixed layer of a liquid crystal compound. The retardation layers each including the stretched film of the resin film are described in, for example, Japanese Patent Application Laid-open No. 2017-54093 or Japanese Patent Application Laid-open No. 2018-60014. Specific examples of the liquid crystal compound and details about a method of forming the alignment fixed layer are described in, for example, Japanese Patent Application Laid-open No. 2006-163343. The descriptions of those publications are incorporated herein by reference.

The thickness of each of the retardation layers may be typically set to such a thickness that the layer may appropriately function as a λ/4 plate. When the retardation layers are each a stretched film of a resin film, the thickness of each of the retardation layers may be, for example, from 10 μm to 50 μm. When the retardation layers are each an alignment fixed layer of a liquid crystal compound, the thickness of each of the retardation layers may be, for example, from 1 μm to 5 μm.

### D-2. Retardation Layer Having Laminated Structure

When the retardation layers each have a laminated structure (substantially a two-layer structure), in typical cases, one of the two layers may function as a λ/4 plate, and the other thereof may function as a λ/2 plate. In the illustrated example described above, the H layer functions as a λ/2 plate, and the Q layer functions as a λ/4 plate. Therefore, the thickness of each of the H layer and the Q layer may be adjusted so that a desired in-plane retardation of the λ/2 plate or the λ/4 plate is obtained. In the case where the H layer is a stretched film of a resin film, the thickness of the H layer may be, for example, from 20 μm to 70 μm. In the case where the H layer is an alignment fixed layer of a liquid crystal compound, the thickness of the Q layer may be, for example, from 2 μm to 7 μm. In this case, the in-plane retardation Re(550) of the H layer is preferably from 200 nm to 300 nm, more preferably from 230 nm to 290 nm, still more preferably from 250 nm to 280 nm. The thickness and in-plane retardation Re(550) of the Q layer are as described in the section D-1 for a single layer. As described above, the angle formed by the slow axis of the H layer and the absorption axis of the polarizer is preferably from 10° to 20°, more preferably from 12° to 18°, still more preferably about 15°. As described above, the angle formed by the slow axis of the Q layer and the absorption axis of the polarizer is preferably from 70° to 80°, more preferably from 72° to 80°, still more preferably about 75°. With such configuration, a characteristic close to an ideal reverse wavelength dispersion characteristic can be obtained, and as a result, an extremely excellent antireflection characteristic can be achieved. Materials forming the H layer and the Q layer, methods of forming the layers, the optical characteristics of the layers, and the like are as described in the section D-1 for a single layer.

### E. Another Retardation Layer

As described above, another retardation layer may be a so-called positive C-plate whose refractive index characteristic shows a relationship of nz>nx=ny. When the positive C-plate is used as another retardation layer, reflection in an oblique direction can be satisfactorily prevented, and hence the viewing angle of the antireflection function of the layer (as a result, the image display apparatus) can be widened. As described above, another retardation layer is typically arranged when the retardation layers are each a single layer. The thickness direction retardation Rth(550) of another retardation layer is preferably from −50 nm to −300 nm, more preferably from −70 nm to −250 nm, still more preferably from −90 nm to −200 nm, particularly preferably from −100 nm to −180 nm. Herein, “nx=ny” encompasses not only a case in which nx and ny are strictly equal to each other, but also a case in which nx and ny are substantially equal to each other. That is, the in-plane retardation Re(550) of another retardation layer may be less than 10 nm.

Another retardation layer may be formed of any appropriate material. Another retardation layer is preferably formed of a film containing a liquid crystal material fixed in homeotropic alignment. The liquid crystal material (liquid crystal compound) that can be homeotropically aligned may be a liquid crystal monomer, or may be a liquid crystal polymer. The liquid crystal compound and a method of forming the retardation layer are specifically, for example, a liquid crystal compound and a method of forming the retardation layer described in paragraphs [0020] to [0028] of Japanese Patent Application Laid-open No. 2002-333642. In this case, the thickness of another retardation layer is preferably from 0.5 μm to 10 μm, more preferably from 0.5 μm to 8 μm, still more preferably from 0.5 μm to 5 μm.

### F. Circularly Polarizing Plate

The polarizers, the protective layer (if present), the retardation layers, and another retardation layer (if present) described in the section B to the section E may be provided as an integrated circularly polarizing plate and laminated on a display cell. Therefore, at least one embodiment of the present invention also comprehends such circularly polarizing plate. The circularly polarizing plate may be a single film (laminated film) in which a first portion corresponding to the first image display portion and a second portion corresponding to the second image display portion are integrated with each other, or may be provided as a set of a first circularly polarizing plate to be laminated on the display cell of the first image display portion and a second circularly polarizing plate to be laminated on the display cell of the second image display portion. Details about the respective layers forming the circularly polarizing plate are as described in the section A to the section E for the image display apparatus. A case in which the circularly polarizing plate is the single film is briefly described below.

In the circularly polarizing plate provided as the single film, the first portion corresponding to the first image display portion and the second portion corresponding to the second image display portion are integrated with each other, and a bending center is defined as a boundary between the first portion and the second portion. The boundary between the first portion and the second portion is preferably seamless (has no seams). The first portion has a first polarizer, and a first retardation layer having a circular polarization function or an elliptical polarization function; the second portion has a second polarizer, and a second retardation layer having a circular polarization function or an elliptical polarization function; the first polarizer and the second polarizer are arranged so that their respective absorption axes are in a line-symmetric relationship with respect to the bending center; and the first retardation layer and the second retardation layer are arranged so that their respective slow axes are in a line-symmetric relationship with respect to the bending center. In such circularly polarizing plate, the first retardation layer and the second retardation layer are each preferably an alignment fixed layer of a liquid crystal compound. With such configuration, the boundary between the first portion and the second portion can be made seamless.

The circularly polarizing plate provided as the single film may be produced by, for example, the following method: (a) the first portion and the second portion are defined by using the center of any appropriate elongate substrate in its widthwise direction as a boundary; (b) each of the first portion and the second portion is subjected to alignment treatment, provided that the direction of the alignment treatment is a direction at 45° with respect to the lengthwise direction of each portion when the retardation layer of the portion is a single layer, and the alignment direction of the first portion and the alignment direction of the second portion are line-symmetric with respect to the boundary; (c) a liquid crystal compound is applied to the alignment-treated surface, and the liquid crystal compound is solidified or cured under a state of being aligned to form an alignment fixed layer; and (d) the formed alignment fixed layer is transferred onto an elongate polarizer having an absorption axis in its lengthwise direction typically by a roll-to-roll process. Thus, a circularly polarizing plate having a configuration of “polarizer/retardation layer (alignment fixed layer of the liquid crystal compound: alignment direction: 45°)” can be obtained. When the retardation layer of each portion has the H layer and the Q layer, an alignment fixed layer whose alignment angle is set to 15° with respect to its lengthwise direction and an alignment fixed layer whose alignment angle is set to 75° with respect to its lengthwise direction only need to be sequentially transferred onto the polarizer. Thus, a circularly polarizing plate having a configuration of “polarizer/H layer (alignment fixed layer of the liquid crystal compound: alignment direction: 15°)/Q layer (alignment fixed layer of the liquid crystal compound: alignment direction: 75°)” can be obtained.

### EXAMPLES

Now, the present invention is specifically described by way of Examples. However, the present invention is not limited by these Examples. Measurement methods for characteristics are as described below.

### (1) Thickness

The thickness of a resin film was measured with a digital micrometer (KC-351C manufactured by Anritsu Corporation), and the thickness of any other product was measured with an interference thickness meter (manufactured by Otsuka Electronics Co., Ltd., product name: “MCPD-3000”).

### (2) Retardation Value of Retardation Layer

A sample measuring 50 mm by 50 mm was cut out of a retardation layer used in each of Examples and Comparative Examples, and was adopted as a measurement sample. The in-plane retardation of the produced measurement sample was measured with a retardation-measuring apparatus (product name: “KOBRA-WPR”) manufactured by Oji Scientific Instruments. The in-plane retardation was measured at a wavelength of 590 nm and a temperature of 23° C.

### (3) a* Value and b* Value

An image display apparatus obtained in each of Examples and Comparative Examples was caused to display a black image, and the a* value and b* value of the image were measured with a multi-angle variable automatic measurement spectrophotometer (manufactured by Agilent Technology, product name: “Cary 7000 UMS”).

### Production Example 1: Production of Polarizer

An amorphous polyethylene terephthalate (A-PET) film (manufactured by Mitsubishi Plastics, Inc., product name: NOVACLEAR SH046, thickness: 200 μm) was prepared as a substrate, and its surface was subjected to corona treatment (58 W/m²/min). Meanwhile, PVA (polymerization degree: 4,200, saponification degree: 99.2%) having added thereto 1 wt % of acetoacetyl-modified PVA (manufactured by the Nippon Synthetic Chemical Industry Co. Ltd., product name: Gohsefimer 2200, polymerization degree: 1,200, saponification degree: 99.0% or more, acetoacetyl modification degree: 4.6%) was prepared, and applied so as to have a film thickness after drying of 12 μm, followed by drying under a 60° C. atmosphere by hot-air drying for 10 minutes to produce a laminate in which a PVA-based resin layer was formed on the substrate. Then, the laminate was first stretched in air at 130° C. at a ratio of 2.0 times to provide a stretched laminate. Next, there was performed a step of insolubilizing the PVA-based resin layer containing aligned PVA molecules included in the stretched laminate by immersing the stretched laminate in an insolubilizing aqueous solution of boric acid having a liquid temperature of 30° C. for 30 seconds. In the insolubilizing aqueous solution of boric acid of this step, the boric acid content was set to 3 wt % with respect to 100 wt % of water. The resultant stretched laminate was dyed to produce a colored laminate. The colored laminate is a product obtained by immersing the stretched laminate in a dyeing liquid having a liquid temperature of 30° C. and containing iodine and potassium iodide, to thereby adsorb iodine onto the PVA-based resin layer included in the stretched laminate. An iodine concentration and an immersion time were adjusted so that the polarizer to be obtained had a single layer transmittance of 44.0%. Specifically, in the dyeing liquid, water was used as a solvent, the iodine concentration was set to fall within the range of from 0.08 wt % to 0.25 wt %, and the potassium iodide concentration was set to fall within the range of from 0.56 wt % to 1.75 wt %. A ratio between the concentrations of iodine and potassium iodide was 1 to 7. Next, there was performed a step of subjecting the PVA molecules of the PVA-based resin layer onto which iodine had been adsorbed to cross-linking treatment by immersing the colored laminate in a cross-linking aqueous solution of boric acid at 30° C. for 60 seconds. In the cross-linking aqueous solution of boric acid of this step, the boric acid content was set to 3 wt % with respect to 100 wt % of water, and the potassium iodide content was set to 3 wt % with respect to 100 wt % of water. Further, the resultant colored laminate was stretched in an aqueous solution of boric acid at a stretching temperature of 70° C. at a ratio of 2.7 times in the same direction as that of the stretching in the air, resulting in a final stretching ratio of 5.4 times. Thus, a laminate of “substrate/polarizer (thickness: 5 μm)” was obtained. In the aqueous solution of boric acid of this step, the boric acid content was set to 6.5 wt % with respect to 100 wt % of water, and the potassium iodide content was set to 5 wt % with respect to 100 wt % of water. The resultant laminate was taken out from the aqueous solution of boric acid, and boric acid adhering to the surface of the polarizer was washed off with an aqueous solution having a potassium iodide content of 2 wt % with respect to 100 wt % of water. The washed laminate was dried with warm air at 60° C.

### Production Example 2: Production of Retardation Film Forming Retardation Layer

2-1. Production of Polycarbonate Resin Film 26.2 Parts by mass of isosorbide (ISB), 100.5 parts by mass of 9,9-[4-(2-hydroxyethoxy) phenyl] fluorene (BHEPF), 10.7 parts by mass of 1,4-cyclohexanedimethanol (1,4-CHDM), 105.1 parts by mass of diphenyl carbonate (DPC), and 0.591 part by mass of cesium carbonate (0.2 mass % aqueous solution) serving as a catalyst were each loaded into a reaction vessel. Under a nitrogen atmosphere, as a first step of a reaction, the heating medium temperature of the reaction vessel was set to 150° C. and the raw materials were dissolved while being stirred as required (about 15 minutes).

Then, the pressure in the reaction vessel was changed from normal pressure to 13.3 kPa, and while the heating medium temperature of the reaction vessel was increased to 190° C. in 1 hour, generated phenol was taken out of the reaction vessel.

The temperature in the reaction vessel was kept at 190° C. for 15 minutes. After that, as a second step, the pressure in the reaction vessel was set to 6.67 kPa, the heating medium temperature of the reaction vessel was increased to 230° C. in 15 minutes, and generated phenol was taken out of the reaction vessel. As the stirring torque of the stirrer increased, the temperature was increased to 250° C. in 8 minutes, and in order to remove generated phenol, the pressure in the reaction vessel was reduced to 0.200 kPa or less. After the stirring torque had reached a predetermined value, the reaction was terminated, and the produced reaction product was extruded into water and then pelletized to provide a polycarbonate resin having the following composition: BHEPF/ISB/1,4-CHDM=47.4 mol %/37.1 mol %/15.5 mol %.

The resultant polycarbonate resin had a glass transition temperature of 136.6° C. and a reduced viscosity of 0.395 dL/g.

The resultant polycarbonate resin was vacuum-dried at 80° C. for 5 hours, and then a polycarbonate resin film having a thickness of 120 μm was produced using a film-forming apparatus with a single-screw extruder (manufactured by Isuzu Kakoki, screw diameter: 25 mm, cylinder preset temperature: 220° C.), a T-die (width: 200 mm, preset temperature: 220° C.), a chill roll (preset temperature: 120° C. to 130° C.), and a take-up unit.

### 2-2. Production of Retardation Film

The resultant polycarbonate resin film was laterally stretched with a tenter stretching machine to provide a retardation film having a thickness of 50 μm. At that time, a stretching ratio was 250%, and a stretching temperature was set to from 137° C. to 139° C.

The resultant retardation film had an Re(590) of 147 nm and an Re(450)/Re(550) of 0.89. Further, the retardation film showed a refractive index characteristic of nx>ny=nz.

### Production Example 3: Production of Another Retardation Layer

20 Parts by weight of a side chain-type liquid crystal polymer represented by the below-indicated chemical formula (I) (numbers 65 and 35 in the formula each represent the mol % of a monomer unit, and the polymer is represented in a block polymer body for convenience: weight-average molecular weight: 5,000), 80 parts by weight of a polymerizable liquid crystal compound showing a nematic liquid crystal phase (manufactured by BASF: product name: Paliocolor LC242), and 5 parts by weight of a photopolymerization initiator (manufactured by BASF: product name: IRGACURE 907) were dissolved in 200 parts by weight of cyclopentanone. Thus, a liquid crystal application liquid was prepared. Then, the application liquid was applied to a substrate film (norbornene-based resin film: manufactured by Zeon Corporation, product name: “ZEONEX”) with a bar coater, and was then heated and dried at 80° C. for 4 minutes so that the liquid crystal was aligned. UV light was applied to the liquid crystal layer to cure the liquid crystal layer. Thus, an alignment fixed layer of a liquid crystal compound (liquid crystal alignment fixed layer, thickness: 0.58 μm) serving as another retardation layer was formed on the substrate. The layer had an Re(590) of 0 nm and an Rth(590) of −100 nm, and showed a refractive index characteristic of nz>nx=ny.

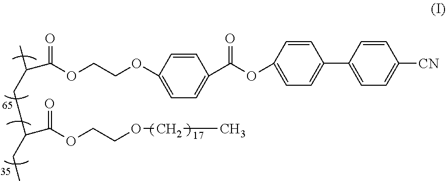

### Production Example 4: Production of Alignment Fixed Layer of Liquid Crystal Compound (Liquid Crystal Alignment Fixed Layer) Forming Retardation Layer

55 Parts of a compound represented by the formula (II), 25 parts of a compound represented by the formula (III), and 20 parts of a compound represented by the formula (IV) were added to 400 parts of cyclopentanone (CPN). After that, the mixture was warmed to 60° C., and was stirred to dissolve the compounds in the solvent. After the dissolution had been confirmed, the temperature of the resultant solution was returned to room temperature, and 3 parts of IRGACURE 907 (manufactured by BASF Japan Ltd.), 0.2 part of MEGAFACE F-554 (manufactured by DIC Corporation), and 0.1 part of p-methoxyphenol (MEHQ) were added to the solution, and the mixture was further stirred to provide a solution. The solution was transparent and uniform. The resultant solution was filtered with a membrane filter having a pore size of 0.20 μm to provide a polymerizable composition. Meanwhile, a polyimide solution for an alignment film was applied to a glass substrate having a thickness of 0.7 mm by using a spin coating method, and was dried at 100° C. for 10 minutes, followed by calcination at 200° C. for 60 minutes. Thus, a coating film was obtained. The resultant coating film was subjected to rubbing treatment to form an alignment film. The rubbing treatment was performed with a commercial rubbing apparatus. The polymerizable composition obtained in the foregoing was applied to the substrate (substantially the alignment film) by a spin coating method, and was dried at 100° C. for 2 minutes. The resultant applied film was cooled to room temperature, and was then irradiated with UV light having an intensity of 30 mW/cm² for 30 seconds through the use of a high-pressure mercury lamp. Thus, a liquid crystal alignment fixed layer was obtained. The liquid crystal alignment fixed layer had an in-plane retardation Re(550) of 130 nm. In addition, the liquid crystal alignment fixed layer had an Re(450)/Re(550) of 0.851, and hence showed a reverse wavelength dispersion characteristic.

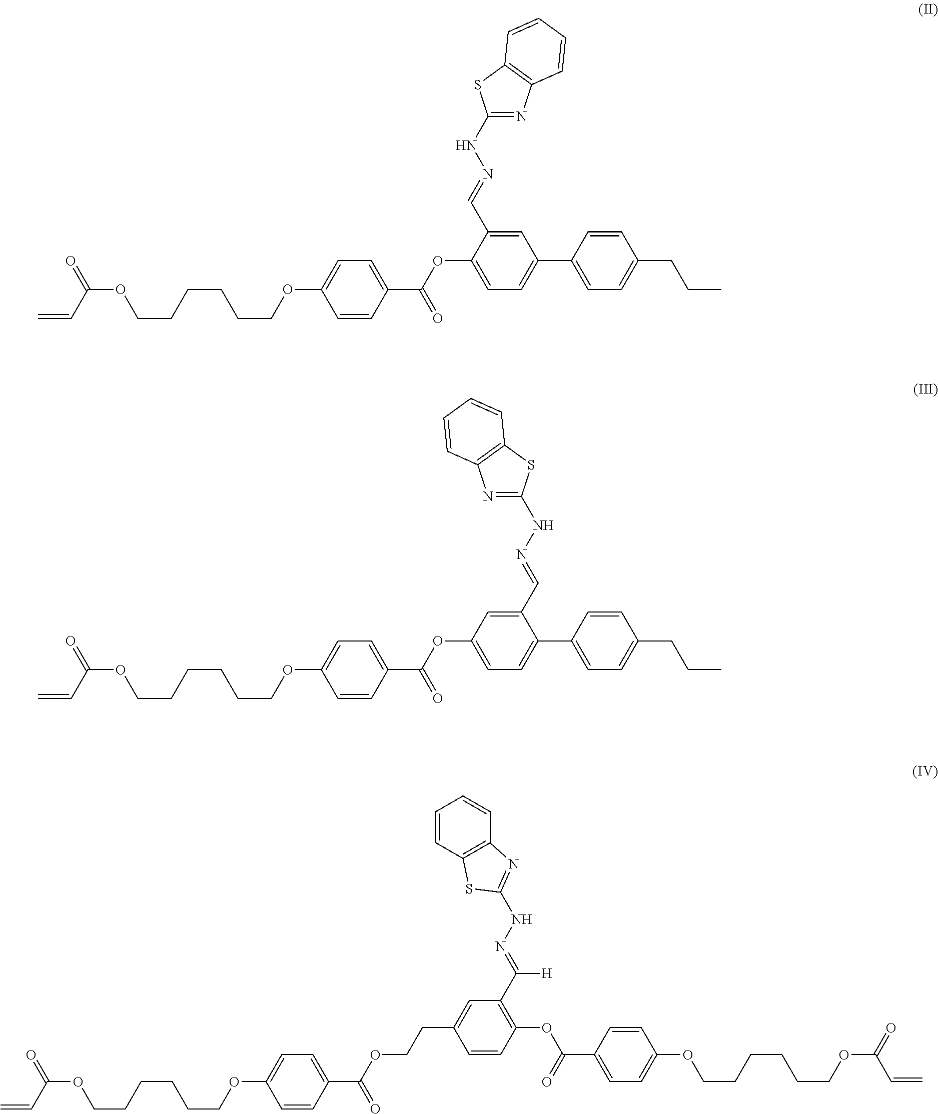

### Production Example 5: Production of Liquid Crystal Alignment Fixed Layer Forming H Layer

10 g of a polymerizable liquid crystal compound showing a nematic liquid crystal phase (manufactured by BASF: product name: “Paliocolor LC242”, represented by the below-indicated formula) and 3 g of a photopolymerization initiator for the polymerizable liquid crystal compound (manufactured by BASF: product name: “IRGACURE 907”) were dissolved in 40 g of toluene to prepare a liquid crystal composition (application liquid).

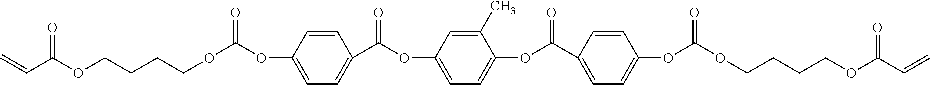 [SMILES: C=CC(=O)OCCCCOC(=O)Oc1ccc(C(=O)Oc2ccc(OC(=O)c3ccc(OC(=O)OCCCCOC(=O)C=C)cc3)c(C)c2)cc1]

The surface of a polyethylene terephthalate (PET) film (thickness: 38 μm) was subjected to alignment treatment in a predetermined direction by rubbing with a rubbing cloth. The liquid crystal application liquid was applied to the alignment-treated surface with a bar coater, and was dried by heating at 90° C. for 2 minutes to align the liquid crystal compound. Light was applied in an irradiance of 1 mJ/cm² to the thus-formed liquid crystal layer with a metal halide lamp to cure the liquid crystal layer. Thus, a liquid crystal alignment fixed layer was formed on the PET film. The liquid crystal alignment fixed layer had a thickness of 2.5 μm and an in-plane retardation Re(590) of 260 nm. The liquid crystal alignment fixed layer showed a positive wavelength dispersion characteristic. Further, the liquid crystal alignment fixed layer showed a refractive index characteristic of nx>ny=nz.

### Production Example 6: Production of Liquid Crystal Alignment Fixed Layer Forming Q Layer

A liquid crystal alignment fixed layer was formed on the PET film in the same manner as in Production Example 5 except that the coating thickness was changed. The liquid crystal alignment fixed layer had a thickness of 1.5 μm and an in-plane retardation Re(590) of 120 nm.

### Example 1

1-1. Production of Polarizing Plate with Retardation Layer

The retardation film (retardation layer) obtained in Production Example 2 was bonded to the polarizer surface of the laminate of “substrate/polarizer” obtained in Production Example 1 via a PVA-based adhesive. In this case, the bonding was performed so that the absorption axis of the polarizer and the slow axis of the retardation layer (retardation film) formed an angle of +45°. Further, the A-PET film that was the substrate was peeled from the laminate, and an acrylic film having a thickness of 40 μm was bonded to the peeled surface via a PVA-based adhesive. Thus, a laminate having a configuration of “protective layer/polarizer/retardation layer” was obtained. Next, the liquid crystal alignment fixed layer (another retardation layer) obtained in Production Example 3 was transferred onto the surface of the retardation layer. Thus, a circularly polarizing plate having a configuration of “protective layer/polarizer/retardation layer/another retardation layer” was obtained. Further, a circularly polarizing plate having a configuration of “protective layer/polarizer/retardation layer/another retardation layer” was obtained in the same manner as that described above except that the angle formed by the absorption axis of the polarizer and the slow axis of the retardation layer (retardation film) was changed to −45°.

### 1-2. Production of Organic EL Display Apparatus

An organic EL panel was removed from an organic EL display apparatus (manufactured by Samsung Electronics Co., Ltd., product name: “Galaxy S5”), and a polarizing film bonded to the organic EL panel was peeled off. Thus, an organic EL cell was obtained. The following two organic EL cells obtained as described above were prepared: an organic EL cell for a left screen and an organic EL cell for a right screen. The circularly polarizing plate obtained in the foregoing was bonded to each of the two organic EL cells. Thus, two organic EL display apparatus were produced. The two organic EL display apparatus were used as a left screen (first image display portion) and a right screen (second image display portion), and the left screen and the right screen were arranged so that the axial angles of their respective polarizers and retardation layers were in a relationship illustrated in FIG. 4B. Thus, an organic EL display apparatus of this example was obtained. The organic EL display apparatus was subjected to the evaluation (3) under a state corresponding to a state in which the left screen and the right screen were bent. More specifically, an a* value and a b* value in a direction at an azimuth angle of 120° and a polar angle of 30° were measured for the left screen, and an a* value and a b* value in a direction at an azimuth angle of 60° and a polar angle of −30° were measured for the right screen. The results are shown in Table 1. An angle in an axial direction in the table is determined as follows: a vertical direction is defined as 0°, a horizontal direction is defined as 90°, an angle in a counterclockwise direction with respect to the vertical direction (0°) is determined as a positive value (no positive sign is shown), and an angle in a clockwise direction with respect thereto is determined as a negative value. In addition, the states of the reflection hues of the left screen and the right screen are shown in FIG. 6 together with the results of Comparative Example 1.

### Examples 2 to 4

Organic EL display apparatus were each produced in the same manner as in Example 1 except that the axial angles of the polarizers and retardation layers of the left screen and the right screen were changed as shown in Table 1. The axial angles of Example 2 correspond to FIG. 1, the axial angles of Example 3 correspond to FIG. 4C, and the axial angles of Example 4 correspond to FIG. 4A. The resultant organic EL display apparatus were subjected to the same evaluations as that of Example 1. The results are shown in Table 1.

### Example 5

Two circularly polarizing plates each having a configuration of “protective layer/polarizer/retardation layer/another retardation layer” were each obtained in the same manner as in Example 1 except that the liquid crystal alignment fixed layer obtained in Production Example 4 was used instead of the retardation film obtained in Production Example 2. An organic EL display apparatus was produced in the same manner as in Example 1 except that those circularly polarizing plates were used. Axial angles in the organic EL display apparatus correspond to FIG. 4B. The resultant organic EL display apparatus was subjected to the same evaluation as that of Example 1. The results are shown in Table 1.

### Examples 6 to 8

Organic EL display apparatus were each produced in the same manner as in Example 5 except that the axial angles of the polarizers and retardation layers of the left screen and the right screen were changed as shown in Table 1. The axial angles of Example 6 correspond to FIG. 1, the axial angles of Example 7 correspond to FIG. 4C, and the axial angles of Example 8 correspond to FIG. 4A. The resultant organic EL display apparatus were subjected to the same evaluations as that of Example 1. The results are shown in Table 1.

### Example 9

Two circularly polarizing plates each having a configuration of “protective layer/polarizer/H layer/Q layer” were each obtained in the same manner as in Example 1 except that the liquid crystal alignment fixed layers obtained in Production Examples 5 and 6 were used instead of the retardation film obtained in Production Example 2. An organic EL display apparatus was produced in the same manner as in Example 1 except that those circularly polarizing plates were used. The resultant organic EL display apparatus was subjected to the same evaluation as that of Example 1. The results are shown in Table 1.

### Examples 10 to 12

Organic EL display apparatus were each produced in the same manner as in Example 9 except that the axial angles of the polarizers and retardation layers of the left screen and the right screen were changed as shown in Table 1. The resultant organic EL display apparatus were subjected to the same evaluations as that of Example 1. The results are shown in Table 1.

### Comparative Examples 1 to 4

Organic EL display apparatus were each produced in the same manner as in Example 1 except that the axial angles of the polarizers and retardation layers of the left screen and the right screen were changed as shown in Table 1. That is, the organic EL display apparatus were each produced in the same manner as in Example 1 except that the absorption axes of the polarizers of the left screen and the right screen were formed so as not to be in a line-symmetric positional relationship with respect to the bending portion, and the slow axes of the retardation layers thereof were also formed so as not to be in a line-symmetric positional relationship with respect thereto. The resultant organic EL display apparatus were subjected to the same evaluations as that of Example 1. The results are shown in Table 1. In addition, the states of the reflection hues of the left screen and right screen of the organic EL display apparatus of Comparative Example 1 are shown in FIG. 6 together with the results of Example 1.

### Comparative Examples 5 to 8

Organic EL display apparatus were each produced in the same manner as in Example 5 except that the axial angles of the polarizers and retardation layers of the left screen and the right screen were changed as shown in Table 1. That is, the organic EL display apparatus were each produced in the same manner as in Example 5 except that the absorption axes of the polarizers of the left screen and the right screen were formed so as not to be in a line-symmetric positional relationship with respect to the bending portion, and the slow axes of the retardation layers thereof were also formed so as not to be in a line-symmetric positional relationship with respect thereto. The resultant organic EL display apparatus were subjected to the same evaluations as that of Example 1. The results are shown in Table 1.

### Comparative Examples 9 to 12

Organic EL display apparatus were each produced in the same manner as in Example 9 except that the axial angles of the polarizers and retardation layers of the left screen and the right screen were changed as shown in Table 1. That is, the organic EL display apparatus were each produced in the same manner as in Example 9 except that the absorption axes of the polarizers of the left screen and the right screen were formed so as not to be in a line-symmetric positional relationship with respect to the bending portion, and the slow axes of the retardation layers thereof were also formed so as not to be in a line-symmetric positional relationship with respect thereto. The resultant organic EL display apparatus were subjected to the same evaluations as that of Example 1. The results are shown in Table 1.

TABLE 1

| | | | | | | | | | | | | | | | | | Left screen | |
|---|---|---|---|---|---|---|---|---|---|---|---|---|---|---|---|---|---|---|
| | | | | | | | | | | | | | | | | | regular reflection | |
| | | | | | | | | | | | | | Left screen | | Right screen | | characteristic | |
| | | | | | | | | | | | | | regular reflection | | regular reflection | | at polar angle of | |
| | | | Left screen | | | | | Right screen | | | | | characteristic | | characteristic | | 30°-right screen | |
| | | | | Retardation layer | | | | | Retardation layer | | | | Azimuth angle | | Azimuth angle | | regular reflection | |
| | Retardation layer | | Polarizer | or H layer | | Q layer | | Polarizer | or H layer | | Q layer | | 120° Polar | | 60° Polar | | characteristic | |
| | (H layer in case | | Absorption | Re | Slow | Re | Slow | Absorption | Re | Slow | Re | Slow | angle 30° | | angle −30° | | at polar angle of −30° | |
| | of lamination) | Q layer | axis | (590) | axis | (590) | axis | axis | (590) | axis | (590) | axis | a* | b* | a* | b* | Δa* | Δb* |
| | Unit | | | | | | | | | | | | | | | | | |
| | — | — | ° | nm | ° | nm | ° | ° | nm | ° | nm | ° | — | — | — | — | — | — |
| Example 1 | Reverse | — | 90 | 147 | 45 | — | — | 90 | 147 | −45 | — | — | −1.34 | −2.13 | −1.39 | −1.79 | 0.05 | −0.34 |
| | dispersion | | | | | | | | | | | | | | | | | |
| | λ/4 film | | | | | | | | | | | | | | | | | |
| Example 2 | Reverse | — | 0 | 147 | 45 | — | — | 0 | 147 | −45 | — | — | −1.55 | −0.60 | −1.61 | −0.58 | 0.06 | −0.02 |
| | dispersion | | | | | | | | | | | | | | | | | |
| | λ/4 film | | | | | | | | | | | | | | | | | |
| Example 3 | Reverse | — | 45 | 147 | 90 | — | — | −45 | 147 | 90 | — | — | −1.87 | −0.62 | −1.76 | −0.56 | −0.11 | −0.06 |
| | dispersion | | | | | | | | | | | | | | | | | |
| | λ/4 film | | | | | | | | | | | | | | | | | |
| Example 4 | Reverse | — | 45 | 147 | 0 | — | — | −45 | 147 | 0 | — | — | −1.79 | −0.54 | −1.64 | −0.45 | −0.15 | −0.09 |
| | dispersion | | | | | | | | | | | | | | | | | |
| | λ/4 film | | | | | | | | | | | | | | | | | |
| Example 5 | Reverse | — | 90 | 147 | 45 | — | — | 90 | 147 | −45 | — | — | −2.77 | −2.43 | −2.89 | −2.53 | 0.12 | 0.10 |
| | dispersion | | | | | | | | | | | | | | | | | |
| | λ/4 liquid | | | | | | | | | | | | | | | | | |
| | crystal | | | | | | | | | | | | | | | | | |
| Example 6 | Reverse | — | 0 | 147 | 45 | — | — | 0 | 147 | −45 | — | — | −1.76 | −1.53 | −1.89 | −1.66 | 0.13 | 0.13 |
| | dispersion | | | | | | | | | | | | | | | | | |
| | λ/4 liquid | | | | | | | | | | | | | | | | | |
| | crystal | | | | | | | | | | | | | | | | | |
| Example 7 | Reverse | — | 45 | 147 | 90 | — | — | −45 | 147 | 90 | — | — | −1.86 | −1.88 | −1.60 | −1.99 | −0.26 | 0.11 |
| | dispersion | | | | | | | | | | | | | | | | | |
| | λ/4 liquid | | | | | | | | | | | | | | | | | |
| | crystal | | | | | | | | | | | | | | | | | |
| Example 8 | Reverse | — | 45 | 147 | 0 | — | — | −45 | 147 | 0 | — | — | −2.54 | −3.01 | −2.55 | −2.87 | 0.01 | −0.14 |
| | dispersion | | | | | | | | | | | | | | | | | |
| | λ/4 liquid | | | | | | | | | | | | | | | | | |
| | crystal | | | | | | | | | | | | | | | | | |
| Example 9 | Positive | Positive | 90 | 260 | 75 | 120 | 15 | 90 | 260 | 105 | 120 | 165 | −0.91 | −2.12 | −1.21 | −1.68 | 0.30 | −0.44 |
| | dispersion | dispersion | | | | | | | | | | | | | | | | |
| | λ/2 liquid | λ/4 liquid | | | | | | | | | | | | | | | | |
| | crystal | crystal | | | | | | | | | | | | | | | | |
| Example 10 | Positive | Positive | 0 | 260 | 75 | 120 | 15 | 0 | 260 | 105 | 120 | 165 | −1.54 | −1.61 | −1.05 | −1.71 | −0.49 | 0.10 |
| | dispersion | dispersion | | | | | | | | | | | | | | | | |
| | λ/2 liquid | λ/4 liquid | | | | | | | | | | | | | | | | |
| | crystal | crystal | | | | | | | | | | | | | | | | |
| Example 11 | Positive | Positive | 45 | 260 | 60 | 120 | 120 | −45 | 260 | 60 | 120 | 120 | −1.77 | −0.45 | −1.44 | −0.54 | −0.33 | 0.09 |
| | dispersion | dispersion | | | | | | | | | | | | | | | | |
| | λ/2 liquid | λ/4 liquid | | | | | | | | | | | | | | | | |
| | crystal | crystal | | | | | | | | | | | | | | | | |
| Example 12 | Positive | Positive | 45 | 260 | −30 | 120 | 30 | −45 | 260 | −30 | 120 | 30 | −1.21 | −1.75 | −1.39 | −1.13 | 0.18 | −0.62 |
| | dispersion | dispersion | | | | | | | | | | | | | | | | |
| | λ/2 liquid | λ/4 liquid | | | | | | | | | | | | | | | | |
| | crystal | crystal | | | | | | | | | | | | | | | | |
| Comparative | Reverse | — | 90 | 147 | 45 | — | — | 90 | 147 | 45 | — | — | −1.48 | −2.20 | −0.40 | −2.08 | −1.08 | −0.12 |
| Example 1 | dispersion | | | | | | | | | | | | | | | | | |
| | λ/4 film | | | | | | | | | | | | | | | | | |
| Comparative | Reverse | — | 0 | 147 | 45 | — | — | 0 | 147 | 45 | — | — | −1.80 | −0.96 | −0.68 | −0.59 | −1.12 | −0.37 |
| Example 2 | dispersion | | | | | | | | | | | | | | | | | |
| | λ/4 film | | | | | | | | | | | | | | | | | |
| Comparative | Reverse | — | 45 | 147 | 90 | — | — | 45 | 147 | 90 | — | — | −1.51 | −0.46 | −2.61 | −1.51 | 1.10 | 1.05 |
| Example 3 | dispersion | | | | | | | | | | | | | | | | | |
| | λ/4 film | | | | | | | | | | | | | | | | | |
| Comparative | Reverse | — | 45 | 147 | 0 | — | — | 45 | 147 | 0 | — | — | −1.78 | −0.57 | −0.80 | −2.17 | −0.98 | 1.60 |
| Example 4 | dispersion | | | | | | | | | | | | | | | | | |
| | λ/4 film | | | | | | | | | | | | | | | | | |
| Comparative | Reverse | — | 90 | 147 | 45 | — | — | 90 | 147 | 45 | — | — | −1.67 | −1.43 | −2.99 | −2.99 | 1.32 | 1.56 |
| Example 5 | dispersion | | | | | | | | | | | | | | | | | |
| | λ/4 liquid | | | | | | | | | | | | | | | | | |
| | crystal | | | | | | | | | | | | | | | | | |
| Comparative | Reverse | — | 0 | 147 | 45 | — | — | 0 | 147 | 45 | — | — | −1.90 | −2.02 | −2.94 | −3.29 | 1.04 | 1.27 |
| Example 6 | dispersion | | | | | | | | | | | | | | | | | |
| | λ/4 liquid | | | | | | | | | | | | | | | | | |
| | crystal | | | | | | | | | | | | | | | | | |
| Comparative | Reverse | — | 45 | 147 | 90 | — | — | 45 | 147 | 90 | — | — | −2.40 | −2.81 | −3.84 | −3.91 | 1.44 | 1.10 |
| Example 7 | dispersion | | | | | | | | | | | | | | | | | |
| | λ/4 liquid | | | | | | | | | | | | | | | | | |
| | crystal | | | | | | | | | | | | | | | | | |
| Comparative | Reverse | — | 45 | 147 | 0 | — | — | 45 | 147 | 0 | — | — | −1.54 | −0.76 | −2.84 | −1.93 | 1.30 | 1.17 |
| Example 8 | dispersion | | | | | | | | | | | | | | | | | |
| | λ/4 liquid | | | | | | | | | | | | | | | | | |
| | crystal | | | | | | | | | | | | | | | | | |
| Comparative | Positive | Positive | 90 | 260 | 75 | 120 | 15 | 90 | 260 | 75 | 120 | 15 | −1.74 | −2.56 | −0.40 | −2.08 | −1.34 | −0.48 |
| Example 9 | dispersion | dispersion | | | | | | | | | | | | | | | | |
| | λ/2 liquid | λ/4 liquid | | | | | | | | | | | | | | | | |
| | crystal | crystal | | | | | | | | | | | | | | | | |
| Comparative | Positive | Positive | 0 | 260 | 75 | 120 | 15 | 0 | 260 | 75 | 120 | 15 | −1.64 | −1.71 | −1.14 | −0.62 | −0.50 | −1.09 |
| Example 10 | dispersion | dispersion | | | | | | | | | | | | | | | | |
| | λ/2 liquid | λ/4 liquid | | | | | | | | | | | | | | | | |
| | crystal | crystal | | | | | | | | | | | | | | | | |
| Comparative | Positive | Positive | 45 | 260 | 60 | 120 | 120 | 45 | 260 | 60 | 120 | 120 | −1.90 | −0.47 | −1.03 | −2.08 | −0.87 | 1.61 |
| Example 11 | dispersion | dispersion | | | | | | | | | | | | | | | | |
| | λ/2 liquid | λ/4 liquid | | | | | | | | | | | | | | | | |
| | crystal | crystal | | | | | | | | | | | | | | | | |
| Comparative | Positive | Positive | 45 | 260 | 30 | 120 | −30 | 45 | 260 | 30 | 120 | −30 | −1.94 | −1.88 | −0.80 | −2.17 | −1.14 | 0.29 |
| Example 12 | dispersion | dispersion | | | | | | | | | | | | | | | | |
| | λ/2 liquid | λ/4 liquid | | | | | | | | | | | | | | | | |
| | crystal | crystal | | | | | | | | | | | | | | | | |

### <Evaluation>

As is apparent from Table 1, according to Examples of the present invention, an image display apparatus in which a difference in regular reflection hue between an image on a left screen and an image on a right screen is small can be obtained.

The image display apparatus of the present invention is suitably used in, for example, a television, a display, a cellular phone, a personal digital assistant, a digital camera, a video camera, a portable game machine, a car navigation system, a copying machine, a printer, a facsimile, a watch, or a microwave oven.

Many other modifications will be apparent to and be readily practiced by those skilled in the art without departing from the scope and spirit of the invention. It should therefore be understood that the scope of the appended claims is not intended to be limited by the details of the description but should rather be broadly construed.

What is claimed is:

1. An image display apparatus, comprising:
a first image display portion;
a second image display portion; and
a bending center defined as a straight line of a connecting portion between one side of the first image display portion and one side of the second image display portion,
the first image display portion and the second image display portion being formed so as to be bendable at the bending center,
the first image display portion having a first polarizer, a first retardation layer having one of a circular polarization function and an elliptical polarization function, and a first display cell in the stated order from a viewer side,
the second image display portion having a second polarizer, a second retardation layer having one of a circular polarization function and an elliptical polarization function, and a second display cell in the stated order from the viewer side,
the first polarizer and the second polarizer being arranged so that respective absorption axes thereof are in a line-symmetric relationship with respect to the bending center,
the first retardation layer and the second retardation layer being arranged so that respective slow axes thereof are in a line-symmetric relationship with respect to the bending center.

2. The image display apparatus according to claim 1, wherein a regular reflection hue (a*₁, b*₁) of the first image display portion in a direction at a polar angle of 30° and a regular reflection hue (a*₂, b*₂) of the second image display portion in the direction at a polar angle of 30° satisfy the following relationships.

|a*₁−a*₂|<1.00

|b*₁−b*₂|<1.00

3. The image display apparatus according to claim 1,
wherein each of the first retardation layer and the second retardation layer is a single layer, and each of the retardation layers has an Re(550) of from 100 nm to 180 nm, and
wherein an angle formed by the slow axis of the first retardation layer and the absorption axis of the first polarizer is from 40° to 50°, and an angle formed by the slow axis of the second retardation layer and the absorption axis of the second polarizer is from 40° to 50°.

4. The image display apparatus according to claim 3,
wherein the first image display portion further has a retardation layer showing a refractive index characteristic of nz>nx=ny between the first retardation layer and the first display cell, and
wherein the second image display portion further has a retardation layer showing a refractive index characteristic of nz>nx=ny between the second retardation layer and the second display cell.

5. The image display apparatus according to claim 1,
wherein each of the first retardation layer and the second retardation layer has a laminated structure of an H layer and a Q layer, each of the H layers has an Re(550) of from 200 nm to 300 nm, and each of the Q layers has an Re(550) of from 100 nm to 180 nm,
wherein an angle formed by a slow axis of the H layer of the first retardation layer and the absorption axis of the first polarizer is from 10° to 20°, and an angle formed by a slow axis of the Q layer of the first retardation layer and the absorption axis of the first polarizer is from 70° to 80°, and
wherein an angle formed by a slow axis of the H layer of the second retardation layer and the absorption axis of the second polarizer is from 10° to 20°, and an angle formed by a slow axis of the Q layer of the second retardation layer and the absorption axis of the second polarizer is from 70° to 80°.

6. The image display apparatus according to claim 1, wherein the first image display portion and the second image display portion are integrated with each other, and the bending center is defined as a boundary between the first image display portion and the second image display portion.

7. The image display apparatus according to claim 1, wherein the image display apparatus is an organic electroluminescence display apparatus.

8. A circularly polarizing plate to be used in the image display apparatus of claim 1, comprising:
a first portion corresponding to the first image display portion;
a second portion corresponding to the second image display portion; and
a bending center,
wherein the first portion and the second portion are integrated with each other,
wherein the bending center is defined as a boundary between the first portion and the second portion,
wherein the first portion has a first polarizer, and a first retardation layer having one of a circular polarization function and an elliptical polarization function,
wherein the second portion has a second polarizer, and a second retardation layer having one of a circular polarization function and an elliptical polarization function, and
wherein the first polarizer and the second polarizer are arranged so that respective absorption axes thereof are in a line-symmetric relationship with respect to the bending center, and the first retardation layer and the second retardation layer are arranged so that respective slow axes thereof are in a line-symmetric relationship with respect to the bending center.

9. The circularly polarizing plate according to claim 8, wherein each of the first retardation layer and the second retardation layer is an alignment fixed layer of a liquid crystal compound.

10. The circularly polarizing plate according to claim 8, wherein each of the first polarizer and the second polarizer is an alignment fixed layer of a liquid crystal compound.
